(19) United States
(12) Patent Application Publication
(10) Pub. No.: US 2013/0269998 A1
(43) Pub. Date: Oct. 17, 2013

(54) SYSTEM AND METHOD FOR OPTIMIZING AND COMBINING ADHESIVE PARAMETERS

(71) Applicants: Benjamin J. POPE, Sunnyvale, CA (US); Ashutosh Y. SHUKLA, Santa Clara, CA (US)

(72) Inventors: Benjamin J. POPE, Sunnyvale, CA (US); Ashutosh Y. SHUKLA, Santa Clara, CA (US)

(73) Assignee: Apple Inc., Cupertino, CA (US)

(21) Appl. No.: 13/446,503

(22) Filed: Apr. 13, 2012

(51) Int. Cl. H05K 7/14; B32B 7/12; D03D 15/00; B32B 37/12

(52) U.S. Cl. 174/535; 156/306.6; 428/343; 428/114; 428/194; 428/354; 442/186

(57) ABSTRACT

The described embodiment relates generally to the field of adhesives. More specifically the described embodiment allows a thin adhesive layer to have additional properties not otherwise available in a homogenous adhesive layer. By combining a variety of adhesive material types into a thin interlocked adhesive layer, properties such as multi-surface adhesion, electrical conductivity, and thermal conductivity can be achieved in a robust adhesive layer.

### BACKGROUND

1. Technical Field

The described embodiment relates generally to the combination of a number of adhesives in a single adhesive giving that adhesive layer a combination of characteristics otherwise unachievable by a layer made of only one adhesive type.

2. Related Art

Different kinds of adhesives are often useful for bonding to different substrates, or are optimized for specialized purposes. For example, it is difficult to bond to silicone rubber and as a result, specialized silicone adhesives have been developed. Unfortunately, however, the specialized silicone adhesives do not adhere well to other substrates. Similarly, while acrylic adhesives bond well to stainless steel, for example, they do not bond well to silicones. An industry standard revolves around layering the adhesives with a liner in between: silicone adhesive on one side, acrylic adhesive on the other, and a plastic film in between the layers. While an improvement over using only an acrylic or only a silicone adhesive, the multi-layer solution can be suboptimal for several reasons including delamination between layers and especially overall thickness (due to the non-functional plastic film layer).

Therefore, what is desired is a practical way to combine a number of types of adhesives into a robust adhesive construct, having a reduced thickness as compared to currently available adhesive constructs.

### SUMMARY OF THE DESCRIBED EMBODIMENTS

This paper describes many embodiments that relate to an apparatus, method and electronic device for enabling reliable, low profile, and robust means for bonding a number of substrates together.

In one embodiment a composite adhesive layer is disclosed. The composite adhesive layer includes at least the following elements: (1) a first adhesive interlocking component; and (2) a second adhesive interlocking component, where the first and second adhesive interlocking components cooperate to hold the first and second adhesive interlocking components of the composite adhesive layer together.

In another embodiment a method is disclosed. The method is for manufacturing an adhesive assembly. The method includes the following steps: (1) receiving a first substrate formed of a first material; (2) receiving a second substrate formed of a second material; (3) receiving a composite adhesive layer, comprised of a first and second adhesive interlocking component, wherein the first and second adhesive interlocking components cooperate to hold the first and second adhesive interlocking components of the composite adhesive layer together.; and (4) bonding the first and second substrates together by arranging the composite adhesive layer between the first and second substrates. The first and second adhesive components are designed to cooperate to improve a property of the bond between the first and second substrates.

In a further embodiment an electronic device is disclosed. The electronic device includes at least the following elements: (1) an electronic device housing; (2) an electronic component; and (3) a first composite adhesive layer which includes at least a first adhesive interlocking component and a second adhesive interlocking component. The first composite adhesive layer forms a bond between the electronic component and a first portion of the electronic device housing. The first and second adhesive interlocking components are formulated to have preferred bonding adhesion with the first portion of the electronic device housing and the electronic component respectively.

Other apparatuses, methods, features and advantages of the disclosure will be or will become apparent to one with skill in the art upon examination of the following figures and detailed description. It is intended that all such additional systems, methods, features and advantages be included within this description, be within the scope of the disclosure, and be protected by the accompanying claims.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 illustrates a conventional laminate structure adhesive assembly;

FIG. 2A illustrates a composite adhesive layer made up of alternating strips of different adhesive material in accordance with the described embodiment;

FIG. 2B illustrates a composite adhesive layer made up of alternating strips of different adhesive material having varying widths determined by relative bonding strength;

FIG. 3 illustrates a composite adhesive layer made up of alternating strips of different adhesive material having interlocking features designed to oppose shearing forces in accordance with the described embodiment;

FIG. 4 illustrates an adhesive layer having a checkerboard configuration in accordance with the described embodiment;

FIG. 5A illustrates a cross-sectional view of a composite adhesive layer disposed between two substrate layers which have substantially different material properties;

FIG. 5B illustrates the effects of outside forces on the composite adhesive layer previously illustrated in FIG. 5A;

FIG. 6A illustrates a woven composite adhesive layer made of two different adhesive types;

FIG. 6B illustrates a cross-sectional view of the composite adhesive layer illustrated in FIG. 6A and disposed between an upper and lower substrate;

FIG. 6C illustrates a second cross-sectional view of the composite adhesive layer illustrated in FIG. 6A allowing a comparison of adhesion positions across the surface area of the adhesive layer.

FIG. 7A illustrates a woven composite adhesive layer made of two different adhesive types having a slight different placement of the adhesive types when compared with FIG. 6A;

FIG. 7B illustrates a cross-sectional view of the composite adhesive layer illustrated in FIG. 7A and disposed between an upper and lower substrate;

FIG. 7C illustrates a second cross-sectional view of the composite adhesive layer illustrated in FIG. 7A allowing a comparison of adhesion positions across the surface area of the composite adhesive layer;

FIG. 8 illustrates a composite adhesive layer having adhesive strips infused with conductive elements;

FIG. 9A illustrates a cross-sectional view of a composite adhesive layer infused with conductive elements and arranged between two similar substrates;

FIG. 9B illustrates the effects of compression on the composite adhesive layer illustrated in the cross-sectional view of FIG. 9A.

FIG. 10A illustrates a woven composite adhesive layer made of three different adhesive types allowing two substrates having different material properties to be bonded together while simultaneously allowing electrical current to pass between the two substrates;

FIG. 10B illustrates a woven composite adhesive layer made of three different adhesive types allowing three substrates having different material properties to be bonded together;

FIG. 11 illustrates an electrical component mounted to the housing of an electronic device in accordance with the described embodiment;

FIG. 12 illustrates a composite adhesive layer with a hydrophobic adhesive arranged around the periphery of the layer to protect an inner adhesive portion of the composite adhesive layer from moisture; and

FIG. 13 shows a flowchart describing a process for using the described embodiment in a manufacturing process.

### DETAILED DESCRIPTION OF EXAMPLE EMBODIMENTS

A representative apparatus and application of methods according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

There are a broad range of adhesive materials used in today's manufacturing industry. Adhesives are generally broken into two broad categories: pressure sensitive adhesives (PSAs); and temperature sensitive adhesives (TSAs). PSAs are generally activated with pressure, while TSAs generally go through a curing process which generally requires exposure to high temperatures. Both types tend to work best with specific types of material and in specific environmental conditions. For example, many pressure sensitive adhesives are designed to bond and hold properly at room temperature but lose their tack at low temperature and have reduced shear holding ability at high temperatures. Other adhesives can be very effective bonding to metal, while only attaching weakly to other materials such as silicone rubber. Consequently, components having disparate material properties cannot always be bonded with a single adhesive layer. In cases where a single adhesive is insufficient manufacturers typically resort to a three layer construct. A first adhesive layer bonds firmly to one substrate. The first adhesive layer is attached to a first surface of a plastic carrier to which it also bonds firmly. A second adhesive layer is then bonded to a second surface of the plastic carrier to which it bonds firmly. Finally, the second adhesive layer bonds firmly to another substrate. This three layer adhesive construct thereby allows firm adhesion between the two substrates. Unfortunately, the aforementioned three layer construct has some disadvantages. Most notably since the construction includes three layers it tends to be significantly thicker than a corresponding single layer adhesive. While efforts can be made to reduce the thickness of the adhesive and plastic carrier layers these respective layers can only be thinned so much before its adhesive properties begin to be compromised. The minimal thickness of such three layer constructs tends to be about 0.2 mm. For the sake of comparison single layer acrylic based adhesive strips can be as thin as 0.01 mm but are more typically closer to a range of 0.05 to 0.1 mm; therefore the difference in thickness can be greater than an order of magnitude. In electronic device enclosures with limited space this additional thickness can cause serious problems. For example, in some cases the added thickness can cause a component to exceed its space allocation forcing designers to make costly modification to an otherwise feasible design. The three layer adhesive construct can also suffer from delamination problems when any one of its many adhesive connections fails.

One solution to the aforementioned problems is to combine a variety of adhesives into a single layer. A single layer minimizes the number of intervening layers and therefore can reduce the odds of delamination inside the adhesion layer. Furthermore, the integration of multiple adhesive types into a single layer reduces the height of an adhesive layer. Removal of the carrier layer alone can result in significant reductions in thickness. The resulting single layer adhesive can be used for a number of purposes including the following: bonding together materials having different compositions; and enabling electrical and thermal conduction between materials. The single layer adhesive construction can have a number of different embodiments. The adhesive layers will generally be arranged between two substrate layers constituting an adhesive assembly.

In a first embodiment an adhesive layer can be formed having alternating adhesive strips with different material properties. Since the chemistry of adhesives tends to be similar the alternating adhesive strips can generally adhere to one another creating a continuous adhesive layer. Depending on the adhesive selection this configuration can allow the adhesive layer to bond to two materials with significantly different material properties, such as metal and silicone rubber. In cases where one adhesive type forms a significantly stronger bond than the other adhesive type the relative width of the stronger adhesive can be reduced to equalize the bond strength of the two adhesives resulting in a stronger overall bond. In another similar embodiment, adhesive strips having strong adhesive properties can be mixed with adhesive strips having weak adhesive properties. The weak adhesive strips can include in one embodiment conductive elements allowing electrical grounding between two bonded materials. In some cases the strong adhesive strips can be a temperature sensitive adhesive which tends to have more adhesive strength than similarly sized pressure sensitive adhesives. This improved bonding strength can negate the loss in adhesive surface area caused by the conductive adhesive strips with much weaker adhesive properties.

In a second embodiment an adhesive layer can be formed having alternating adhesive strips made from different adhesive types and having interlocking features joining the different types of adhesive strips. Interlocking features arranged between the adhesive strips allow a two distinct advantages: (1) they increase the surface area between the adhesive strips, and since the load path in this type of adhesive configuration passes between adjacent adhesive strips, more surface area results in a stronger bond between adjacent adhesive strips; (2) the interlocking features tend to prevent shear forces from allowing adjacent adhesive strips from sliding back and forth.

In a third embodiment an adhesive layer can be formed having a checkerboard configuration where adhesive material is arranged in squares. When an external load is placed upon an adhesive assembly, individual adhesive squares are connected to adhesive squares of different type on four sides strengthening the inter adhesive bond that opposes the external load. The checkerboard configuration is also good at resisting shearing forces as each adhesive square is stabilized with adhesive squares having a different adhesive type on all four sides.

In a fourth embodiment adhesive strips can be woven into an interleaved pattern. The interleaved pattern significantly increases the surface area between adhesive strips made of different adhesive types. The woven interleaving configuration of at least two adhesive types allows an adhesive strip in contact with a substrate layer to which it does not naturally adhere, to be pinned to it by another adhesive strip that does naturally adhere to that substrate layer, thereby creating strong interlocking properties between the adhesive types. In this way an adhesive layer with strong inter adhesive bonds can be achieved.

In a fifth embodiment an adhesive layer can be formed having alternating adhesive strips having different material properties and heights. Strong non-conductive adhesive strips can be formed shorter than adjacent conductive strips. When the substrate layers press against the adhesive layer the taller conductive strips receive a greater amount of compressive force than the non-conductive adhesive strips due to their greater height. This can be desirable as conductive adhesive strips generally have better conductive properties when put under great amounts of compression. This is because conductive elements embedded within conductive adhesive strips are forced closer together, thereby forming a more solid conductive path for electricity to travel through. Consequently, the compressed adhesive layer can be used in situations where improved grounding is desired.

In a sixth embodiment a woven adhesive layer can be formed having three or more different types of adhesive. This can be advantageous when 3 or more substrates requiring different adhesive types need to be bonded together. Alternatively, the three adhesive types can be useful when a grounding conduit is desired between two different bonded substrates. In that case one of the three adhesive types can be infused with conductive elements.

In a final embodiment the described embodiment can be applied to an electronic device. An electronic component can require mounting and grounding in an electronic device. In this embodiment the electronic component is the tallest single component in the device; therefore, its overall height probably dictates the overall height of the electronic device enclosure. In this case anything that can be done to decrease the height of this component is to decrease the component's height. When the portion of the electronic component to be attached to the electronic device enclosure is silicone and the electronic device enclosure itself is metal a single adhesive type may not be sufficient to properly bond the two components. Since a conventional solution may be unacceptably thick the described embodiment can be utilized to reduce the overall size of the electronic device. A silicone based adhesive will firmly bond to the silicone portion of the electronic component, and an acrylic adhesive can be used to firmly bond to the metal electronic device enclosure. Any of the previously described embodiments can be used to merge the two adhesive types together and form a single layer having a desirably small overall thickness.

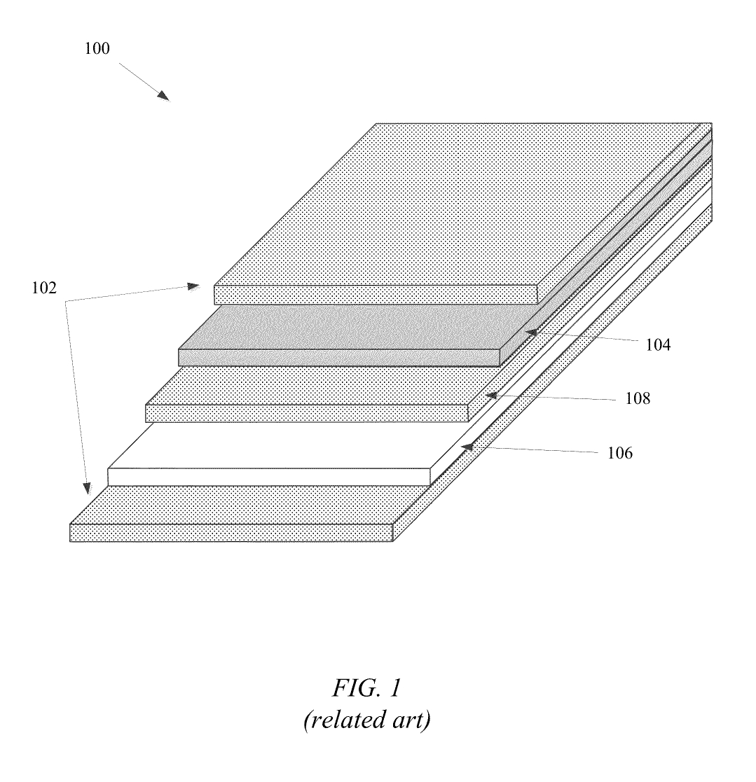

These and other embodiments are discussed below with reference to FIGS. 1-13; however, those skilled in the art will readily appreciate that the detailed description given herein with respect to these figures is for explanatory purposes only and should not be construed as limiting.

FIG. 1 illustrates a conventional laminate structure adhesive assembly 100. The conventional laminate structure 100 closely resembles two sided tape. Liner layers 102 function to protect adhesive layers 104 and 106 prior to being utilized. When laminate structure 100 is ready for use liner layers 102 are removed to expose adhesive layers 104 and 106 for use. Adhesive layers 104 and 106 can have substantially different adhesive properties as long as they are both able to firmly bond to carrier layer 108. Carrier layer 108 can be made from a stiff plastic material such as Polyethylene Terephthalate (PET). In addition to acting as a common adhesive substrate carrier layer 108 can provide rigidity to laminate structure 100. In this way laminate structure 100 can then be used to bond two materials made of substantially different materials. For example, laminate structure 100 can be used to bond a metal substrate to silicone rubber which is notoriously difficult to bond to. Adhesives have been designed specifically to bond to silicone rubber but do not bond well with metals. Therefore, when adhesive layer 106 is a silicone adhesive and adhesive layer 104 is an acrylic adhesive a strong bond can be created between a silicon rubber substrate and a metal substrate. Unfortunately, the resulting laminate structure 100 tends to be quite thick. Where a single layer acrylic adhesive can be as thin as 0.01 mm, laminate structures similar to laminate structure 100 tend to be at least 0.2 mm. When trying to minimize the height of an overall electronic component stackup, such an increase in adhesive height is highly undesirable. Delamination can also be problematic in laminate structure 100. When connecting two different substrate layers laminate structure 100 has a total of 4 different layer connections. Each layer can be susceptible to failure in different environmental situations such as high or low heat, or in environments with too much or too little moisture. If any of these conditions occur then the failure of one of the four bonding layers can cause the entire bond to fail.

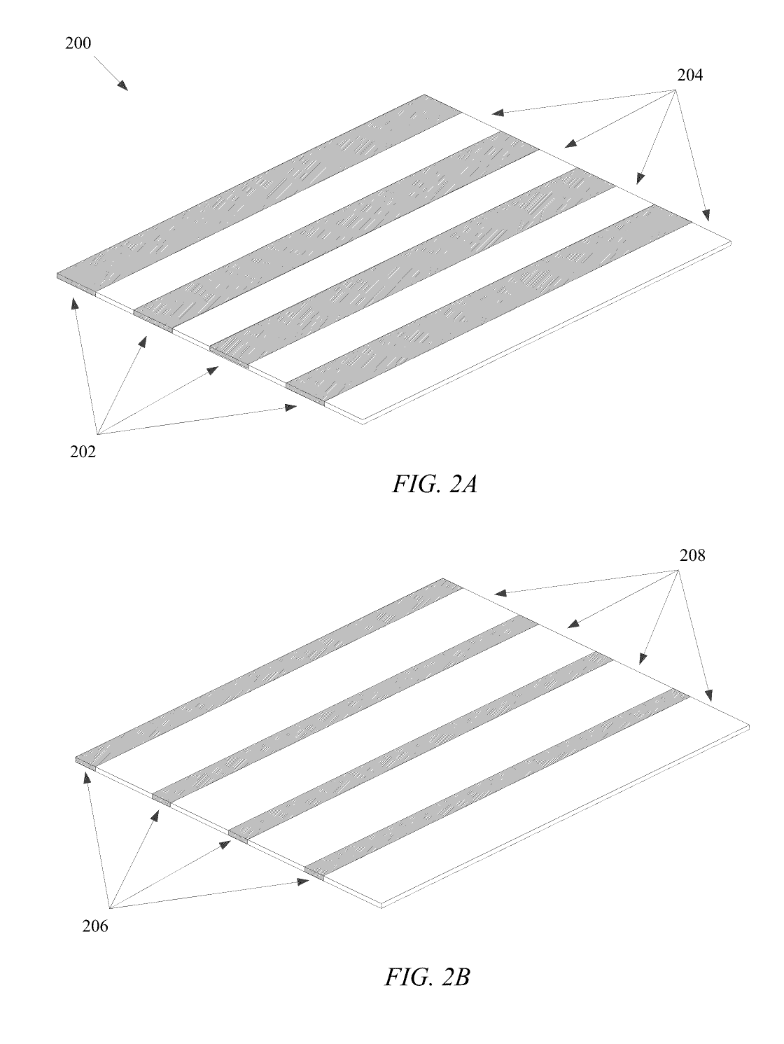

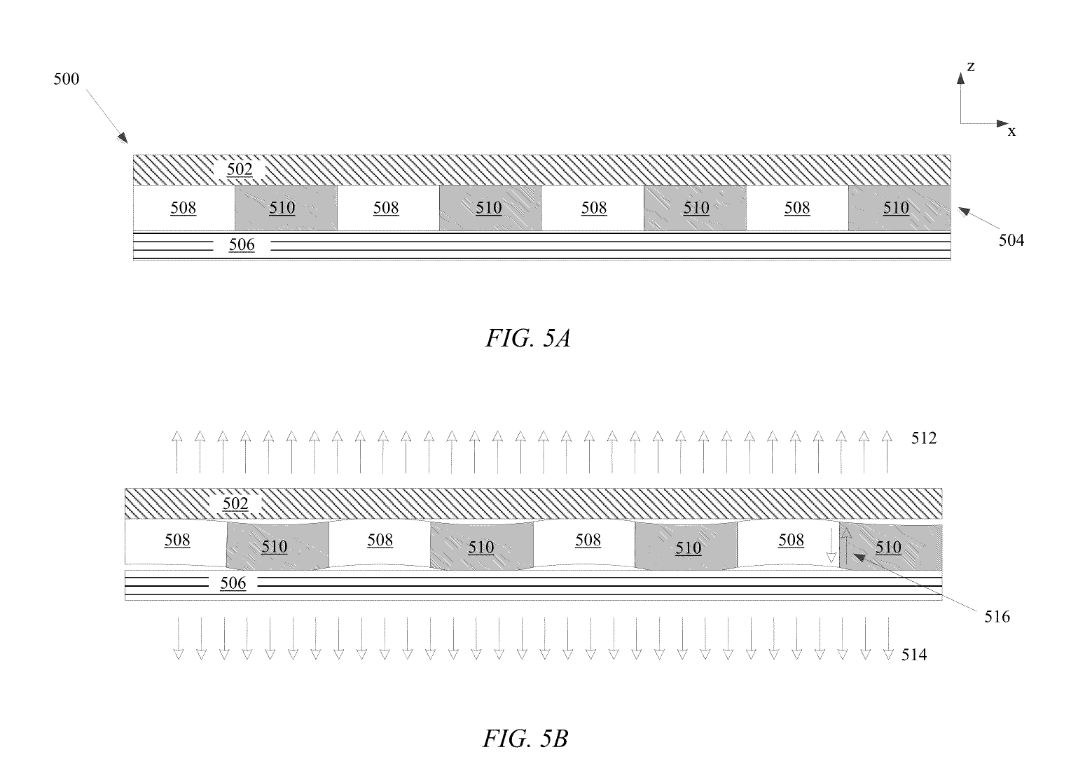

FIGS. 2A and 2B each show a one layer adhesive formed with two different adhesive types. In FIG. 2A a composite adhesive layer 200 is shown with alternating adhesive strips 202 and 204. Adhesive strips 202 can be made from an adhesive type with substantially different adhesive properties than adhesive strips 204. Prior to use, liner layers can cover a top and bottom surface of composite adhesive layer 200. Adhesive strips 202 and 204 can have similar enough chemistry such that intersections between adhesive strips 202 and 204 inherently stick to one another. In this way adhesive interaction along the surface area of the intersections between adhesive strips 202 and 204 can help keep composite adhesive layer 200 together when composite adhesive layer 200 is subjected to stress. The importance of the inter adhesive connections will be further discussed in reference to FIG. 5. FIG. 2B is a variation on the embodiment illustrated in FIG. 2A. Here adhesive strips 206 have been reduced in thickness when compared with adhesive strips 208. This configuration might be desirable when for example, adhesive strips 206 form a stronger bond with its respective substrate than adhesive strips 208. In this way the respective strength of the bonds on each substrate can be equalized thereby forming a stronger overall bond between the two joined substrates.

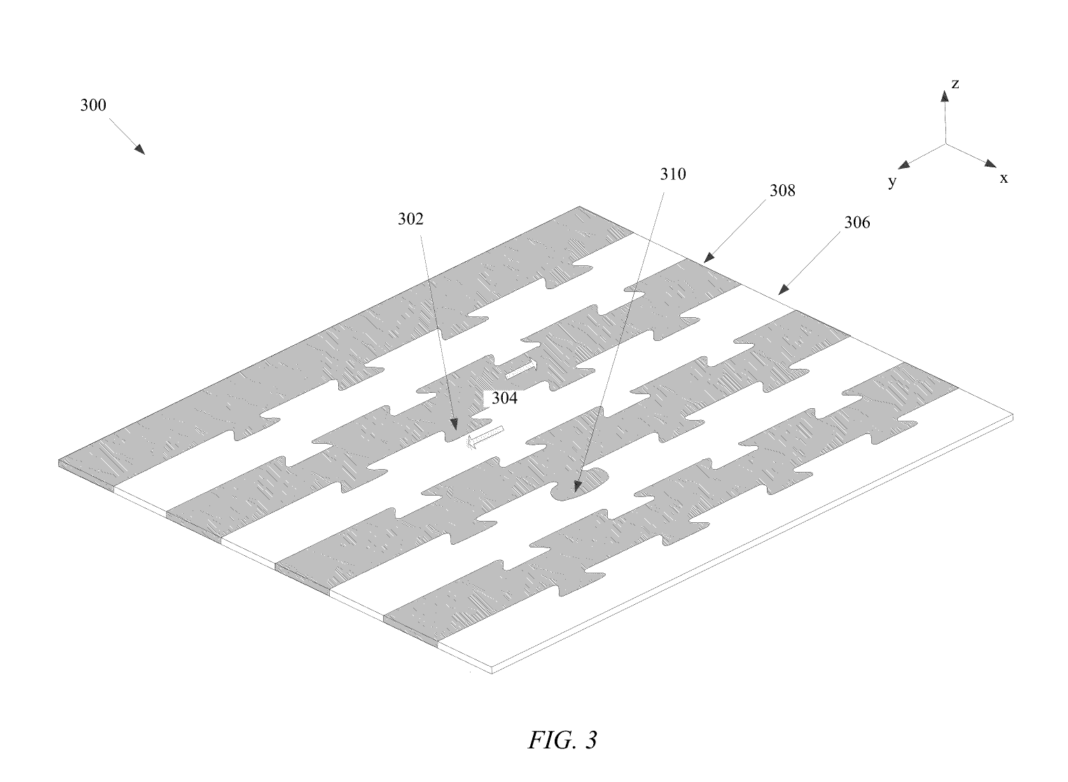

FIG. 3 shows a composite adhesive layer 300 formed with two different adhesive types having interlocking aspects tending to hold the two adhesive types together. Composite adhesive layer 300 can include an interlocking aspect embodied by interlocking feature 302. Interlocking feature 302 can be useful for preventing shearing force 304 in the Y-axis from causing movement between adhesive strips 306 and 308. In addition to combatting shearing forces interlocking feature 302 increases surface area between adhesive strips 306 and 308. Increased surface area between adhesive strips can result in increased adhesion between the substrate layers and composite adhesive layer thereby beneficially strengthening the resulting bond. This increased surface area is particularly important for embodiments in which composite adhesive layer 300 is extremely thin. In some embodiments composite adhesive layer 300 can be as thin as 0.01 mm; however, it is more common for composite adhesive layers to be between 0.05 and 0.1 mm. Regardless, composite adhesive layer 300 will be quite thin and any increase in surface area between the adhesive strips can beneficially strengthen the inter adhesive bond. Consequently, in some embodiments the size and shape of interlocking features 302 can be varied when more or less surface area is required between the adhesive strips. For example, interlocking feature 310 has been expanded to be somewhat larger than the other interlocking features located on composite adhesive layer 300. It should be noted that while composite adhesive layer 300 has adhesive strips 306 and 308 which are of roughly the same width, the width of adjacent adhesive strips can be adjusted to equalize bond strength between the substrate layers, as previously discussed in relation to FIG. 2B.

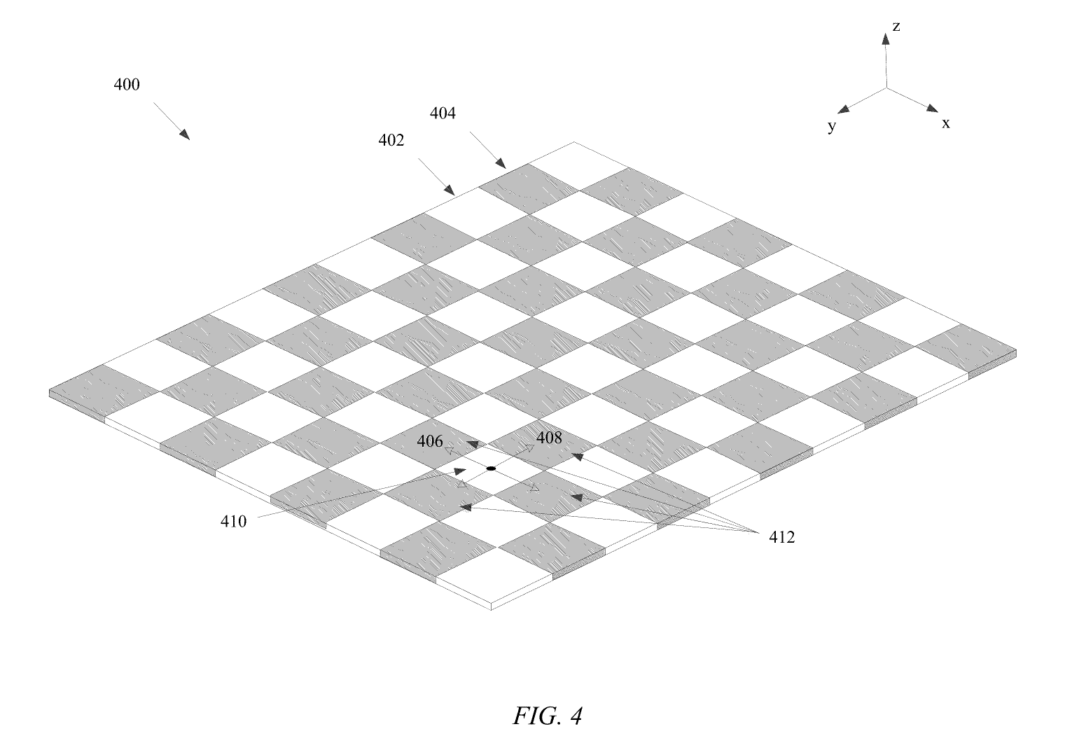

FIG. 4 illustrates a composite adhesive layer with a checkerboard configuration. Composite adhesive layer 400 can include alternating adhesive squares 402 and 404 made of varying adhesive types. In some embodiments adhesive squares 402 and 404 can be shaped like adhesive rectangles, or any other repeatable pattern. By arranging adhesive squares 402 and 404 as illustrated surface area between adhesive types can be increased when compared with less complex patterns. Furthermore, shearing forces in the X-Y plane can be effectively blocked as the interlocking checkerboard configuration prevents movement between the squares. For example, forces 406 and 408 acting upon adhesive square 410 are each opposed by surrounding squares made of different adhesive types and therefore attached to a different substrate. When checkerboard style composite adhesive layer 400 is sandwiched between substrate layers of different materials adhesive square 410 can be strongly bonded to an upper substrate layer while surrounding adhesive squares 412 can be strongly bonded to a lower substrate layer. A shearing force applied to the upper substrate layer in any direction would be effectively blocked by surrounding adhesive squares 412 securely bonded to the lower substrate layer.

FIGS. 5A and 5B show a cross-sectional view of adhesive assembly 500. In FIG. 5A upper substrate layer 502 is bonded to an upper surface of composite adhesive layer 504. Composite adhesive layer 504 can represent any of the aforementioned embodiments described in FIGS. 2-4. Lower substrate layer 506 is bonded to a lower surface of composite adhesive layer 504. Composite adhesive layer 504 can be made from alternating adhesive elements 508 and 510. In this embodiment adhesive elements 508 can be optimized for preferred adhesion to upper substrate layer 502. Adhesive elements 510 can be optimized for preferred adhesion to lower substrate layer 506. It should be noted that while adhesive elements 508 are formulated to attach more aggressively to upper substrate layer 502 there is often a nominal amount of bonding between adhesive elements 508 and lower substrate layer 506. In FIG. 5B stress fields 512 and 514 are displayed. Stress fields 512 and 514 can act in the Z-axis tending to separate upper and lower substrate layers 502 and 506. FIG. 5B shows that when stress fields 512 and 514 are applied to adhesive assembly 500 interconnections between adhesive elements 508 and 510 are subjected to inter adhesive shearing stress 516. In FIG. 5B while adhesive elements are shown actually separating from non-preferred substrate layers this is a more extreme scenario and in general substrate layers 502 and 506 would stay in place under more typical loading scenarios. Since adhesive elements 508 and 510 are often made of substantially similar materials adhesive properties between adhesive elements 508 and 510 can be sufficient to overcome inter adhesive shearing stress 516. As previously discussed, increases in surface area between adhesive elements 508 and 510 can help increase inter adhesive adhesion strength and consequently result in bonds capable of overcoming increased inter adhesive shearing stresses 516.

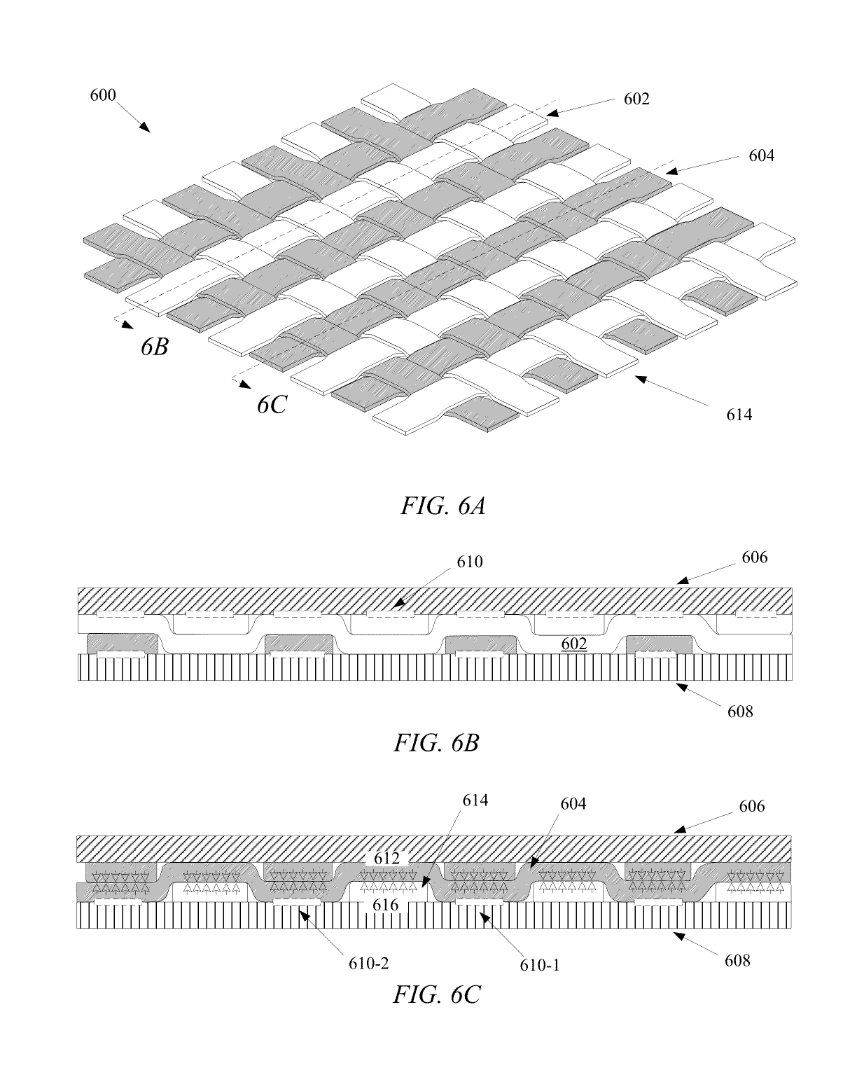

FIGS. 6A-6C show composite adhesive layer 600 arranged in a woven pattern. In this embodiment the woven pattern provides the two adhesive types, represented with darker and lighter shading, significant interlocking properties by increasing surface area between the two adhesive types. Composite adhesive layer 600 is made of a number of adhesive strips which can be arranged so that equal portions of the adhesive strips are exposed to an upper surface and lower surface of composite adhesive layer 600. For example, about half of adhesive strip 602 appears on the upper surface of composite adhesive layer 600 in FIG. 6A. Likewise, about half of adhesive strip 604, made from an adhesive type having different properties than adhesive strip 602, is exposed to the upper surface of composite adhesive layer 600. In this particular weave configuration vertical stripes of similar material are exposed giving a final configuration similar to the composite adhesive layer shown in FIG. 2A. FIG. 6B shows a cross sectional view of composite adhesive layer 600 sandwiched between an upper substrate layer 606 and lower substrate layer 608. In this embodiment the adhesive chemistry of adhesive strip 602 is designed to adhere to upper substrate layer 606. For ease of reference bonding indicator 610 is included in the figures to indicate where an adhesive strip is in contact with a preferred substrate layer. In the cross-section illustrated by FIG. 6B bonding indicators 610 show that about 75% of the adhesive strips are in contact with a preferred substrate layer in this cross-sectional view. Consequently, in the cross-section illustrated by FIG. 6C which exemplifies the other half of connection areas, only 25% of the adhesive strips are in contact with a preferred substrate layer. This constitutes the 50% average adhesion rate expected by such a woven construction. FIG. 6C shows how inter adhesive forces 612 and 614 oppose each other across a broad surface area thereby maximizing inter adhesive force resistance. As illustrated, adhesive strip 604 exerts force 612 on adhesive strip 614 which pushes back with force 616. The portion of adhesive strip 604 exerting force 612 is supported by two preferred bonding attachments to substrate layer 608, indicated by bonding indicator 610-1 and bonding indicator 610-2. Likewise, adhesive strip 614 exerting force 616 is also attached to upper substrate layer 606 in two positions (not shown by this cross-sectional view). In this way, inter adhesive forces are evenly spread across a majority of the area of composite adhesive layer 600.

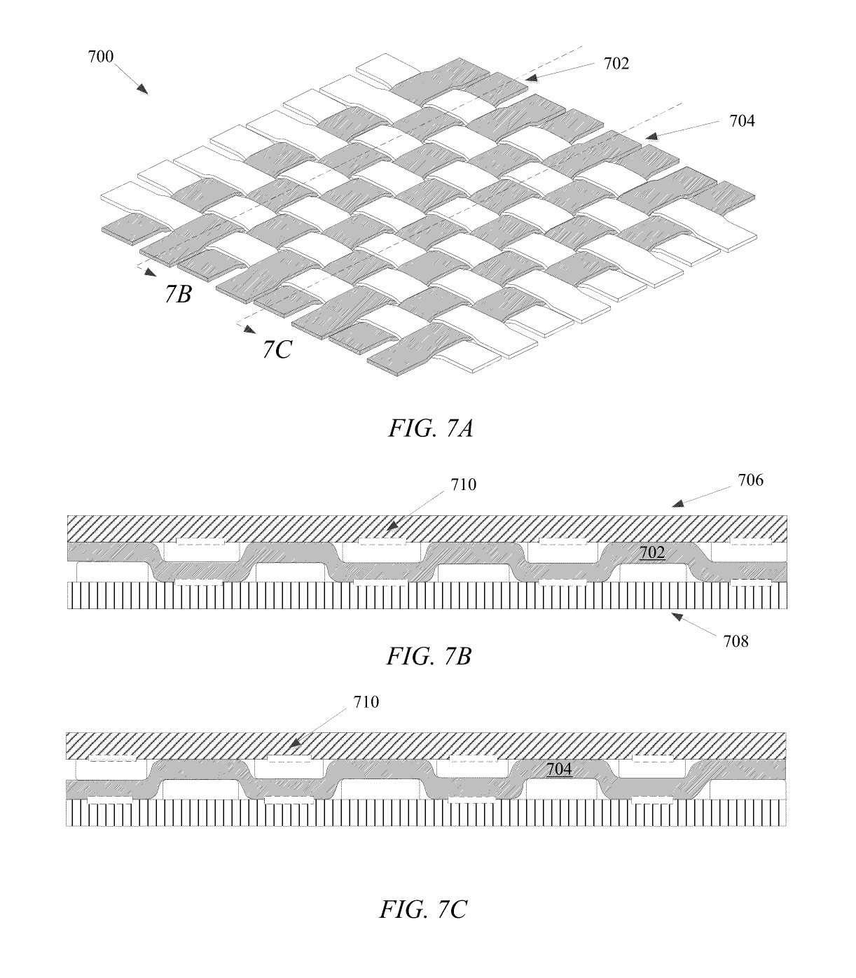

FIGS. 7A-7C show composite adhesive layer 700 arranged in a woven pattern. Composite adhesive layer 700 is made of a number of adhesive strips which appear on both an upper and lower surface of composite adhesive layer 700 in FIG. 7A. In this particular weave configuration a checkerboard configuration is achieved which shares some similarities to the composite adhesive layer shown in FIG. 4; however, by virtue of the woven adhesive strip pattern the two illustrated adhesive types represented by darker and lighter shading are imbued with substantial interlocking properties. FIG. 7B shows a cross sectional view of composite adhesive layer 700 sandwiched between an upper substrate layer 706 and lower substrate layer 708. In this embodiment the adhesive chemistry of adhesive strip 702 is designed to adhere to upper substrate layer 706. As in FIG. 6B bonding indicator 710 is included in the figures to indicate where an adhesive strip is firmly adhered to a substrate layer. In the cross-sections illustrated by FIGS. 7B and 7C bonding indicators 710 show that about 50% of the adhesive strips in contact with a substrate layer form a strong bond. Consequently, adhesive strips embedded in composite adhesive layer 700 come in contact with a preferred substrate layer about the same number of times regardless of position in composite adhesive layer 700. This creates an even adhesive matrix across the surface of each substrate allowing any loading or stress to be evenly spread across the adhesive matrix.

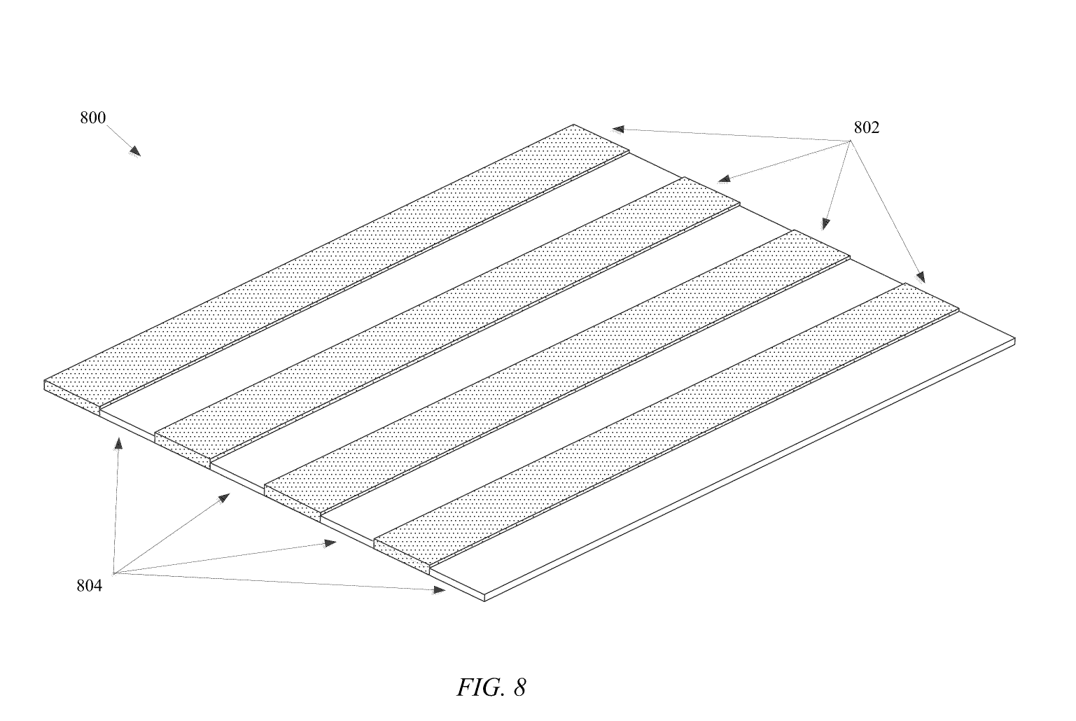

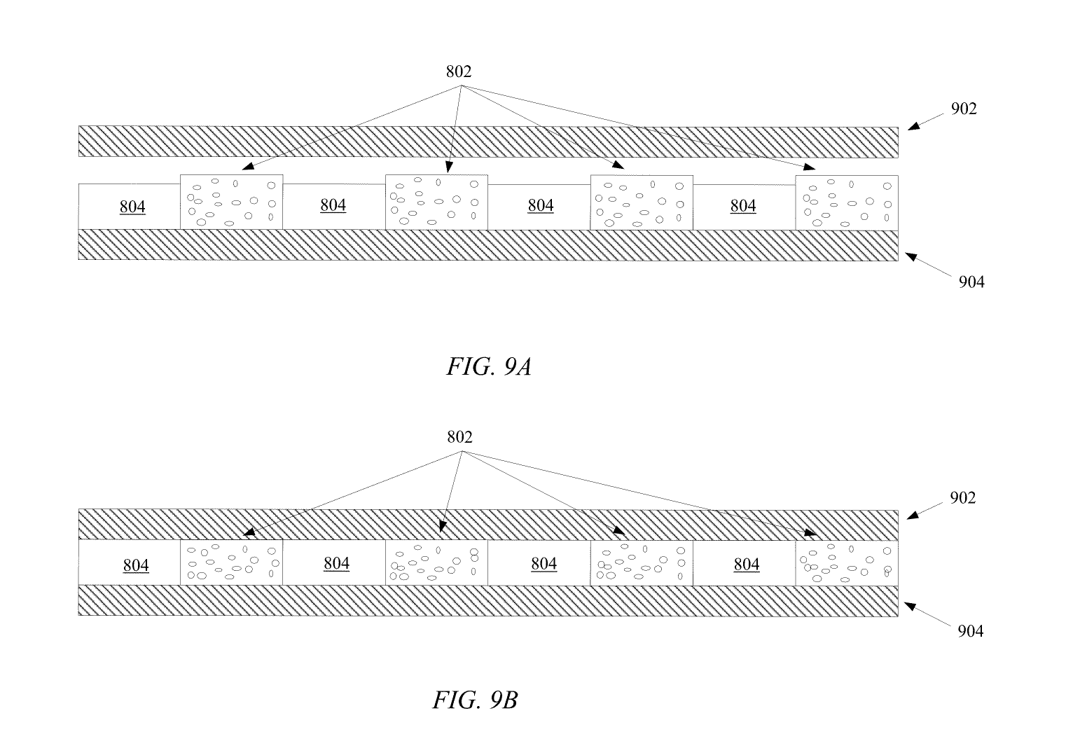

FIG. 8 shows composite adhesive layer 800 including adhesive strips infused with conductive material. An adhesive can be given electrically conductive characteristics by infusing it with small metal particles such as silver, gold or copper. Unfortunately, adhesives infused with conductive materials experience a drop in adhesive performance. Conductive adhesives can be desirable when a component representing one of the substrates requires grounding with the other substrate; however, if the adhesive doesn't hold in place the grounding materials aren't terribly useful. By mixing alternating rows of conductive adhesive strips 802 and nonconductive adhesive strips 804 together, a composite adhesive layer with both strong adhesive properties and conductive properties can be achieved. Composite adhesive layer 800 can be formed with taller conductive adhesive strips 802 than nonconductive adhesive strips 804. This can be advantageous since the conductive performance of conductive adhesives tend to improve under increasing levels of compression. By forming conductive adhesive strips 802 taller than non-conductive strips 804 compression can be applied more heavily to the taller conductive adhesive strips 802 by the upper and lower substrate layers. FIG. 9 more fully illustrates the beneficial effects of compression on the conductive adhesive strips. At this point it should be noted that while FIG. 8 is the first time conductive adhesives have been specifically mentioned with regards to the figures, a set of conductive strips could be substituted for any of the second adhesive types shown in the previous embodiments thereby producing a composite adhesive layer with conductive properties. It should also be noted that conductive adhesive strips 802 and nonconductive strips 804 can have interlocking properties; these interlocking properties can include interlocking features similar to those described in reference to FIG. 3. In some cases such interlocking properties can help maintain the conductive and nonconductive strips together during an assembly process. In other embodiments conductive adhesive strips 802 can have preferred bonding with one substrate while nonconductive strips 804 can have preferred bonding with another substrate. In this case since one layer is taller than the other an interlocking feature on adhesive strips 804 can be completely encased by portions of conductive adhesive strips 802, thereby increasing the strength of the inter adhesive connection.

FIGS. 9A and 9B show composite adhesive layer 800 arranged between upper and lower substrate layers in a variety of states of compression. In FIG. 9A composite adhesive layer 800 lies between upper substrate layer 902 and lower substrate layer 904. In this particular embodiment upper and lower substrate layers 902 and 904 can be made of materials capable of strongly bonding with a single adhesive type; in this case the single adhesive type is the adhesive type forming adhesive strips 804. In this cross-sectional view the height difference between adhesive strips 802 and adhesive strips 804 can be clearly seen. This height differential can be varied depending on the amount of compression required to achieve a desired amount of conductivity. In FIG. 9B substrate layers 902 and 904 have compressed composite adhesive layer 800. Conductive particles infused within conductive adhesive strips 802 have been compressed and are consequently spaced closer together thereby increasing the conductive properties of conductive adhesive strips 802. It should be noted that while conductive strips have been discussed with regards to their electrical conductivity, some situations could arise in which thermal conductivity is desired. In that case the gold, silver, or copper conductive elements could be replaced by carbon or graphite filler. In other embodiments conductive adhesive strips can be a non-adhesive elastomer functioning only to conduct electricity or heat through the composite adhesive layer and relying solely on the non-conductive adhesive strips for adhesion.

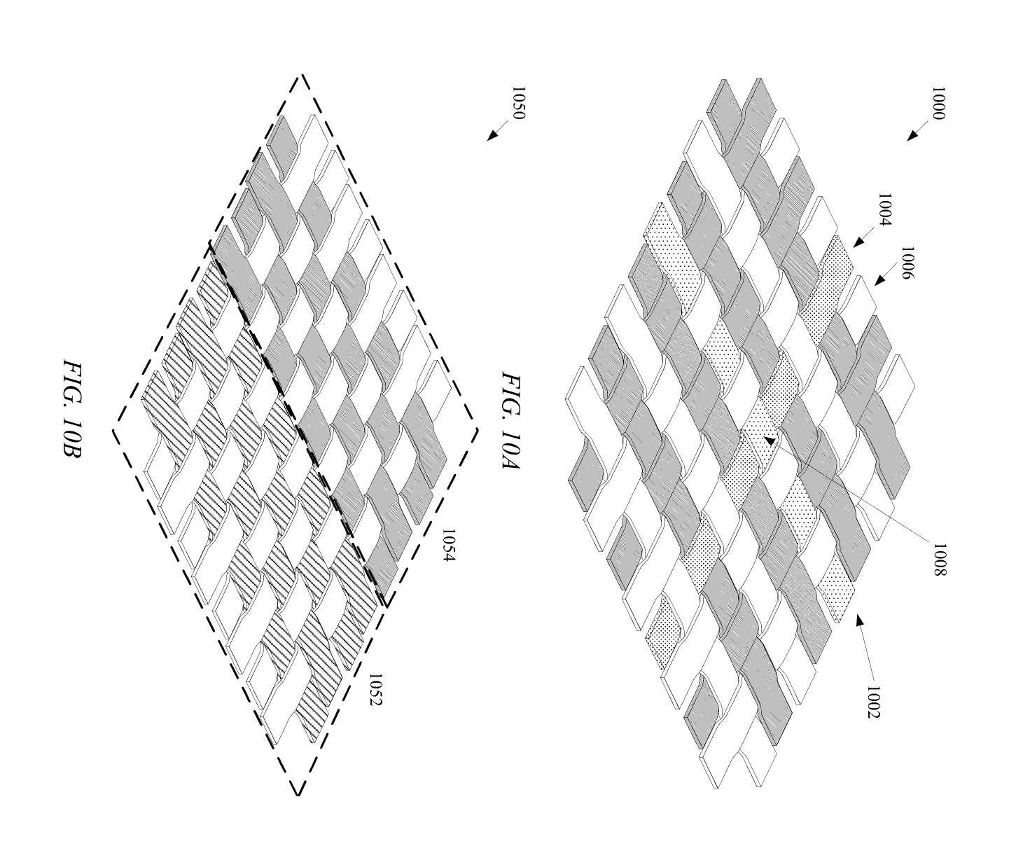

FIGS. 10A and 10B illustrate scenarios in which three adhesive types can be useful in forming composite adhesive layer 1000. FIG. 10A shows composite adhesive layer 1000 arranged in a woven pattern quite similar to the embodiment shown in FIG. 6A, thereby resulting in interlocking between the adhesive strips forming the weave. In this embodiment a third adhesive is introduced into the weave by adhesive strips 1002 and 1004. In one embodiment adhesive strips 1002 and 1004 can be made of the same adhesive type as adhesive strip 1006 with the addition of conductive particles resulting in increased conductivity and decreased adhesion strength. Conduction can be especially effective in region 1008 where adhesive strips 1002 and 1004 overlap and form a conductive pathway extending straight from one surface of composite adhesive layer 1000 to the other. This configuration of composite adhesive layer 1000 can be useful when for example a specific portion of an upper or lower substrate layer requires electrical grounding or increased thermal conductivity. Region 1008 can then be arranged underneath that portion of the substrate layer. In FIG. 10B an alternate configuration is described. In some cases a composite adhesive layer might need to adhere to three surfaces having different material properties. For example, regions 1052 and 1054 of composite adhesive layer 1050 can be in contact with an upper substrate having different material properties over the two regions 1052 and 1054. In this embodiment lower substrate layer can be made of a single material. In this case it can be useful to include adhesive material in composite adhesive layer 1050 capable of bonding all three material types together. It should be noted that while only three different adhesive materials are shown many more can be integrated into such a composite adhesive layer to imbue the composite adhesive layer with a variety of different adhesive properties.

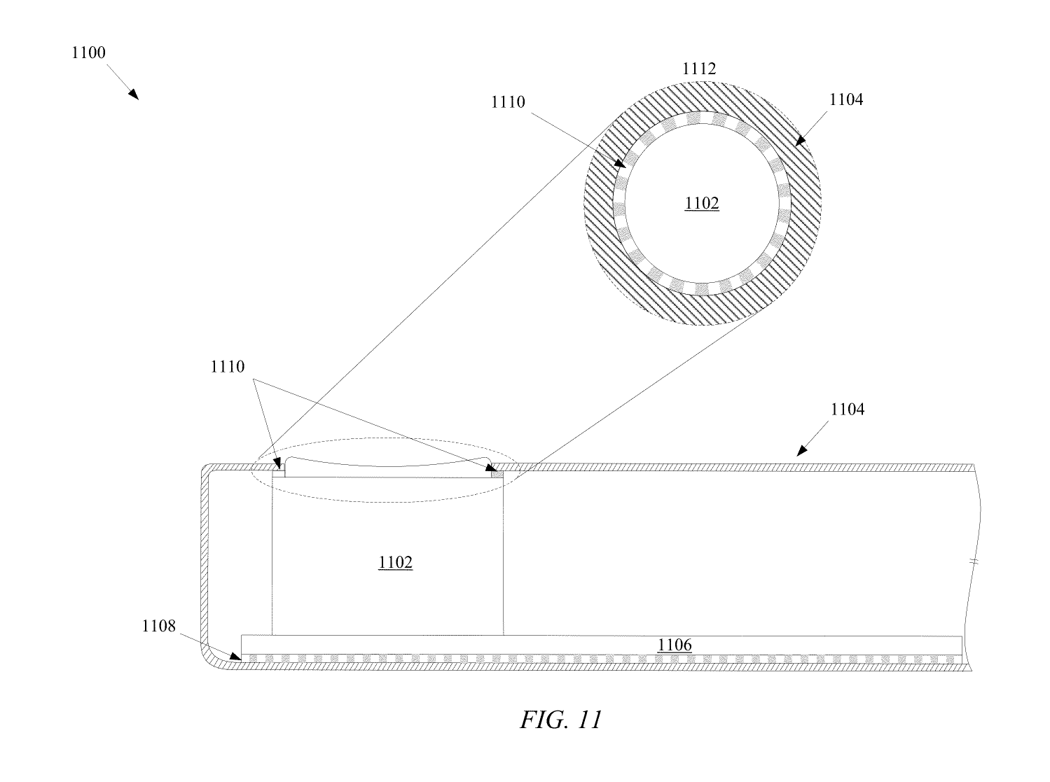

FIG. 11 illustrates a partial cross sectional view of an electronic device 1100. Electronic component 1102 is housed within electronic device housing 1104. In some embodiments electronic component 1102 can be an off the shelf component already attached to printed circuit board (PCB) 1106. Electronic component 1102 itself can be a camera module. PCB 1106 can be made of a silicone based substrate, and in this particular embodiment acts as the aforementioned upper substrate layer. The silicone substrate material of PCB 1106 can require a specific type of adhesive which is not compatible with material properties of an inside surface of electronic device housing 1104. Consequently, composite adhesive layer 1108 will be made up of at least two different types of adhesive material. Adhesive types can be arranged in composite adhesive layer 1108 in accordance with many of the previously described embodiments. Electronic component 1102 can be grounded to electronic device housing 1104 through adhesive layer 1108 by inserting or weaving a few adhesive strips into adhesive layer 1108. Here electronic device housing 1104 can be considered to be the lower substrate layer. In this embodiment any reduction in thickness of composite adhesive layer 1108 can beneficially reduce the height of electronic device housing 1104 thereby producing a more pocketable, sleek electronic device. When electronic component 1102 is a camera module additional height can allow for a larger number of glass elements and consequently the potential for a lens with superior optics. Furthermore, when composite adhesive layer 1108 includes a silicone based adhesive, the silicone based adhesive can provide increased shock protection as silicone is good at absorbing and dissipating energy. This can be especially beneficial when mounting a fragile electrical component 1102 such as a camera module, a microphone or even an LCD.

The described embodiment can also be useful for securing a portion of electrical component 1102 against an opening in electronic device housing 1104 through which it can protrude. Adhesive strip 1110 can be arranged to attach an upper surface of electronic component 1102 to electronic device housing 1104. Where adhesive strip 1110 is arranged around a circular opening as it can be when electrical component 1102 is a camera module adhesive strip 1110 can be preformed in a circular pattern with alternating adhesive types aligned in a radial direction. In this way additional properties may be infused into adhesive strip 1110 to enable the joint between electronic device housing 1104 and electronic component 1102 to have additional beneficial properties. In view 1112 a top view of a portion of electronic device 1100 is shown. The radial layout of alternating adhesive types built into adhesive strip 1110 can be clearly seen. The portion of electronic device housing 1104 which covers adhesive strip 1110 has been removed so that the layout of adhesive strip 1110 can be clearly seen. In embodiments where the top portion of electronic component 1102 is made of a similar material to that of electronic device housing 1104 conductive elements can be inserted in the alternating strips to create a grounding path for electronic component 1102.

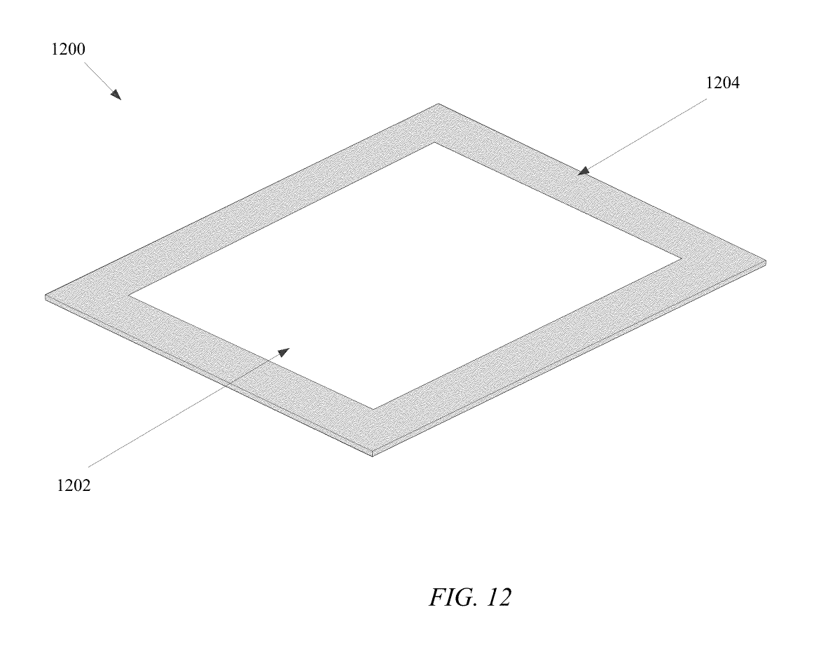

FIG. 12 illustrates a composite adhesive layer made of a strong adhesive type 1202 in the center and a weaker adhesive type 1204 around the periphery. In this embodiment weaker adhesive type 1204 can be hydrophobic. Weaker adhesive type 1204 can protect stronger adhesive type 1202 from any water or moisture. This can be especially desirable when stronger adhesive type 1202 tends to break down when water or moisture comes into contact with it. In this way stronger adhesive type 1202 can bear any mechanical stresses while weaker adhesive type 1204 simultaneously protects stronger adhesive 1202 from any moisture. Devices which must withstand occasional exposure to water and humidity can greatly benefit from such a configuration where a potentially strong adhesive vulnerable to moisture would otherwise be unusable. In other embodiments weaker hydrophobic adhesive type 1204 can protect adhesive type 1202 which is also conductive thereby preventing conductive pathways between bonded substrates from being corroded.

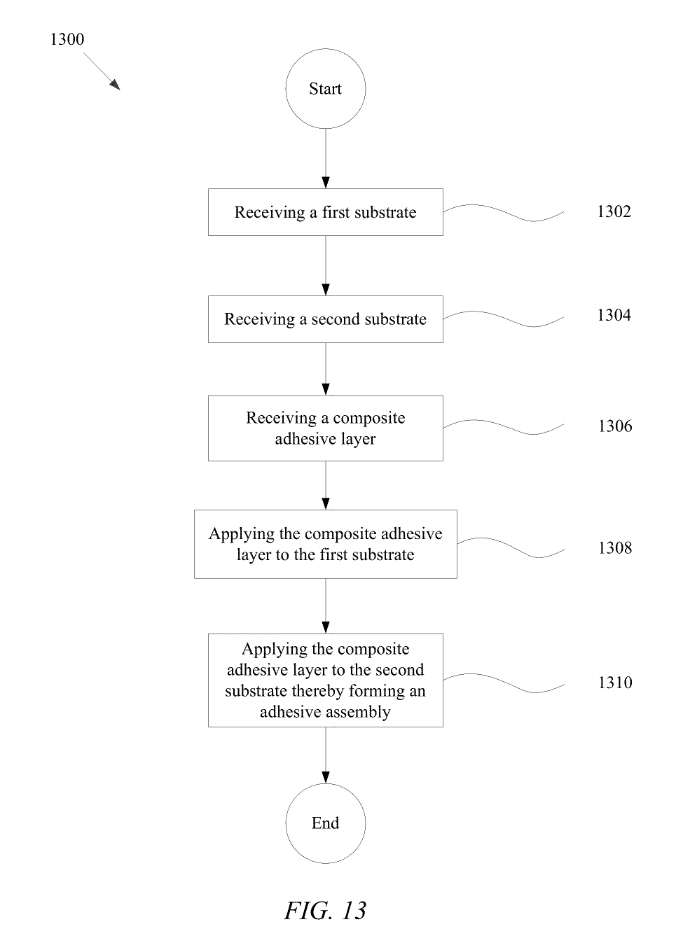

FIG. 13 shows a flow chart detailing a method for assembling an adhesive assembly. In a first step 1302 a first substrate is received. The first substrate can be any component forming a portion of a larger work of manufacture. In a second step 1304 a second substrate is received. The second substrate can be any component that is permanently or temporarily affixed to the first substrate as part of a manufacturing process. In some embodiments portions of the first and second substrate layers to be bonded can be made of the same material, or in other embodiments they can be made of materials with radically different adhesion properties. In step 1306 a composite adhesive layer is received. The composite adhesive layer is configured to reliably bond and/or facilitate conduction (electrical and/or thermal) between the first and second substrates. The composite adhesive layer includes at least two distinct adhesive types which can be arranged together in any of the ways described in the previously described embodiments. In step 1308 the composite adhesive layer is applied to the first substrate layer. In some embodiments this bond will be established by applying pressure between the composite adhesive layer and the first substrate layer, and in other embodiments a certain amount of heat may be applied to the composite adhesive layer to cause it to cure with the first substrate. In step 1310 the composite adhesive layer is applied to the second substrate layer in much the same way it was applied to the first substrate layer, by way of pressure or heat. After the two substrates have been bonded together an adhesive assembly is formed and the method is complete.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A composite adhesive layer, comprising:
a first adhesive interlocking component; and
a second adhesive interlocking component, wherein the first and second adhesive interlocking components cooperate to hold the first and second adhesive interlocking components of the composite adhesive layer together.

2. The composite adhesive layer as recited in claim 1, wherein the first and second adhesive interlocking components are, respectively, a first and second set of adhesive strips, wherein the first and second set of adhesive strips are interweaved together to form an interwoven composite adhesive layer.

3. The composite adhesive layer as recited in claim 2, wherein the interwoven composite adhesive layer exposes about equal amounts of the first and second adhesive components to an upper and lower surface of the composite adhesive layer.

4. The composite adhesive layer as recited in claim 1, wherein the first adhesive interlocking component includes a first interlocking feature and wherein the second adhesive interlocking component includes a second interlocking feature arranged such that the first and second adhesive interlocking features combine to secure the first and second interlocking components together to form the composite adhesive layer.

5. The composite adhesive layer as recited in claim 4, wherein the first and second interlocking components are arranged in alternating parallel strips.

6. The composite adhesive layer as recited in claim 1, further comprising an adhesive assembly, the adhesive assembly comprising:
a first substrate formed of a first material; and
a second substrate formed of a second material ,
wherein the composite adhesive layer is disposed between the first and second substrate, and
further wherein the first adhesive interlocking component has a preferred bonding with the first material of the first substrate, and the second adhesive interlocking component has a preferred bonding with the second material of the second substrate.

7. The composite adhesive layer as recited in claim 6, further comprising:
a third adhesive interlocking component, wherein the third adhesive interlocking component is infused with conductive elements.

8. The adhesive assembly as recited in claim 1, wherein the first adhesive interlocking component is non-conductive.

9. The composite adhesive layer as recited in claim 8, wherein the second adhesive interlocking component is conductive and wherein the conductive second adhesive interlocking component is compressed between a first and second substrate such that conductivity of the compressed conductive second adhesive interlocking component is greater than conductivity of an uncompressed conductive adhesive interlocking component, the non-conductive first adhesive interlocking component subjected to substantially less compression.

10. The adhesive assembly as recited in claim 1, wherein the first adhesive interlocking component is a hydrophobic adhesive, and further wherein the second adhesive is a conductive adhesive, the first adhesive designed to keep moisture from contacting the second adhesive.

11. A method for manufacturing an adhesive assembly, comprising:
receiving a first substrate formed of a first material;
receiving a second substrate formed of a second material;
receiving a composite adhesive layer, comprised of a first and second adhesive interlocking component, wherein the first and second adhesive interlocking components cooperate to hold the first and second adhesive interlocking components of the composite adhesive layer together.; and
bonding the first and second substrates together by arranging the composite adhesive layer between the first and second substrates,
wherein the first and second adhesive components cooperate to improve a property of the bond between the first and second substrates.

12. The method as recited in claim 11, wherein the improved bond property is the capability to bond the first and second materials of the first and second substrate together when the first and second materials cannot be securely bonded with a single type of adhesive.

13. The method as recited in claim 11, wherein the composite adhesive layer is between 0.01 mm and 0.1 mm thick.

14. The method as recited in claim 11, wherein the first and second adhesive interlocking components are adhesive strips, the adhesive strips having interlocking features which combine to secure the adhesive interlocking components of the composite adhesive layer together

15. The method as recited in claim 14, wherein the first adhesive interlocking components are infused with conductive elements and are formed taller than the second adhesive strips, which are nonconductive.

16. The method as recited in claim 15, wherein the arranging that takes place in the bonding step results in compressive force being placed more heavily on the first adhesive interlocking components to increase the conductive properties of the first adhesive interlocking components.

17. An electronic device, comprising:
an electronic device housing;
an electronic component; and
a first composite adhesive layer, comprised of a first adhesive interlocking component and a second adhesive interlocking component,
wherein the first composite adhesive layer forms a bond between the electronic component and a first portion of the electronic device housing, the first and second adhesive interlocking components formulated to have preferred bonding adhesion with the first portion of the electronic device housing and the electronic component respectively.

18. The electronic device as recited in claim 17, the first composite adhesive layer further comprising:
a third adhesive interlocking component infused with thermally conductive elements, allowing heat to be efficiently transferred from the electronic component to the electronic device housing.

19. The electronic device as recited in claim 18, wherein the thermally conductive elements infused in the third adhesive component are selected from the group consisting of carbon filler and graphite filler.

20. The electronic device as recited in claim 17, the electronic device further comprising:
a second composite adhesive layer, comprised of a third and fourth adhesive interlocking component,
wherein the second composite adhesive layer bonds the electronic component to a second portion of the electronic device housing, the third and fourth adhesive interlocking components cooperate with each other to provide an electrical grounding conduit between the electronic component and the second portion of the electronic device housing.

21. The electronic device as recited in claim 17, wherein the first composite adhesive layer is formed as a single layer checkerboard configuration, the interlocking checkerboard pattern providing interlocking properties between the first and second adhesive interlocking components.

22. The electronic device as recited in claim 17, wherein the first adhesive interlocking component is a temperature sensitive adhesive and the second adhesive interlocking component is a pressure sensitive adhesive.
